(19) United States
(12) Patent Application Publication
(10) Pub. No.: US 2025/0201540 A1
(43) Pub. Date: Jun. 19, 2025

(54) PLASMA STATE MONITORING DEVICE FOR CONNECTING TO AN IMPEDANCE MATCHING CIRCUIT FOR A PLASMA GENERATION SYSTEM, PLASMA GENERATION SYSTEM, AND METHOD FOR MONITORING THE PLASMA GENERATION SYSTEM

(71) Applicant: TRUMPF Hüttinger GmbH + Co. KG, Freiburg (DE)

(72) Inventors: Florian A. Maier, Pfaffenweiler (DE); Dorota Burka, Warsaw (PL); Christian Bock, Freiburg (DE); Thomas Sprenger-Lorenz, Freiburg (DE); Clara Ines Kowald, Freiburg im Breisgau (DE)

(21) Appl. No.: 19/064,768

(22) Filed: Feb. 27, 2025

Related U.S. Application Data
(63) Continuation of application No. PCT/EP2023/073880, filed on Aug. 31, 2023.

(30) Foreign Application Priority Data
Aug. 31, 2022 (DE) 10 2022 122 044.3

(51) Int. Cl. H01J 37/32

(52) U.S. Cl. CPC H01J 37/32917; H01J 37/32183; H01J 2237/24564; H01J 2237/327

(57) ABSTRACT

A plasma state monitoring device for connecting to an impedance matching circuit for a plasma generation system is configured to capture a first group of time-varying measured values recorded in a temporally sequential manner, capture a second group of time-varying measured values of at least one measured variable comprising at least one of a voltage, a current, or a phase relationship between the voltage and the current recorded in a temporally sequential manner, represent the first group of time-varying measured values in a first diagram, and represent the second group of time-varying measured values in a second diagram. The second diagram has two axes, one of which is a time axis. The first group of time-varying measured values and the second group of time-varying measured values have been captured within an at least partially identical time period, thereby enabling a state monitoring of the plasma generation system.

### CROSS REFERENCE TO RELATED APPLICATIONS

This application is a continuation of International Application No. PCT/EP2023/073880 (WO 2024/047150 A1), filed on Aug. 31, 2023, and claims benefit to German Patent Application No. DE 10 2022 122 044.3, filed on Aug. 31, 2022. The aforementioned applications are hereby incorporated by reference herein.

### FIELD

Embodiments of the invention relate to a plasma state monitoring device for connecting to an impedance matching circuit for a plasma generation system, to a plasma generation system and to a method for monitoring the plasma generation system.

### BACKGROUND

The surface treatment of workpieces, and e.g. the production of semiconductors using plasma, and the processing of workpieces using gas lasers are industrial processes in which, in particular in a plasma chamber, a plasma is generated by means of a direct current or by means of a high-frequency alternating signal having a working frequency ranging from several tens of kHz to the GHz range. In plasma processes of this type, minor errors can result in very substantial damage.

The plasma chamber is connected via further electronic components, such as coils, capacitors, lines or transformers, to a high-frequency generator (HF generator). These further components can constitute oscillating circuits, filters or impedance matching circuits. The HF generator is customarily configured as a power converter, which converts the conventional mains voltage at a frequency of 50-60 Hz into the desired HF voltage, and thus simultaneously executes the corresponding in-service power conversion.

The plasma process has an issue, in that the electrical load impedance of the plasma chamber (plasma=load) which occurs during the process is dependent upon conditions in the plasma chamber, and can vary substantially. Properties of the workpiece, electrodes and gas ratios are particularly relevant.

High-frequency generators feature a limited working range, with respect to the impedance of the connected electrical load (=consumer). If the load impedance departs from a permissible range, this can result in damage to, or even the destruction of the HF generator.

For this reason, an impedance matching circuit (matchbox) is generally required, which transforms the impedance of the load to a nominal impedance of the generator output.

Various impedance matching circuits are known. Exemplary impedance matching circuits assume a fixed setting and execute a predefined transformation action, and are thus comprised of electrical components, in particular coils and capacitors, which do not undergo any variation during operation. This is particularly appropriate for consistently uniform operation, e.g. as in the case of a gas laser. Impedance matching circuits are further known, in which at least a proportion of the components of impedance matching circuits are mechanically variable. For example, motor-driven rotary capacitors are known, the capacitance value of which can be varied by altering the arrangement of the capacitor plates relative to one another. Multiple switchable reactances are also known, e.g. capacitors which can assume different values.

Considered in broad terms, three impedance ranges can be assigned to a plasma. Prior to ignition, very high impedances are in force, typically of a magnitude in excess of 1 kiloohm. In normal operation, i.e. during regulation operation with plasma, lower impedances are in force, typically of a magnitude lower than 100 ohms. In the event of unwanted local discharges (arcs), or in the event of plasma fluctuations, very low impedances, typically of a magnitude lower than 0.5 ohms, can occur. Aside from these three identified impedance ranges, further specific states, with other associated impedance values, can occur. In the event of an abrupt variation of the load impedance, such that the load impedance or the transformed load impedance departs from a permissible impedance range, the HF generator, or transmission apparatuses between the HF generator and the plasma chamber, can sustain damage. Moreover, plasma states can also occur which are not desirable, but which are nevertheless suggestive of a stable condition.

An impedance matching circuit of this type is described, for example in DE 10 2009 001 355 A1.

On the grounds of the various plasma states, it is not always possible, by reference to impedance, to draw a conclusion as to whether the present plasma state is currently the desired plasma state.

### SUMMARY

Embodiments of the present invention provide a plasma state monitoring device for connecting to an impedance matching circuit for a plasma generation system. The plasma state monitoring device is configured to capture a first group of time-varying measured values. The time-varying measured values in the first group are dependent on an impedance which is detectable on one of terminals of the impedance matching circuit and are recorded in a temporally sequential manner. The plasma state monitoring device is configured to capture a second group of time-varying measured values of at least one measured variable. The at least one measured variable includes at least one of a voltage, a current, or a phase relationship between the voltage and the current. The time-varying measured values of the at least one measured variable in the second group are recorded in a temporally sequential manner. The plasma state monitoring device is configured to represent the first group of time-varying measured values in a first diagram. The first diagram has no time axis. The plasma state monitoring device is configured to represent the second group of time-varying measured values in a second diagram. The second diagram has two axes, one of which is a time axis. The first group of time-varying measured values and the second group of time-varying measured values have been captured within an at least partially identical time period. Thereby, a state monitoring of the plasma generation system is enabled.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows one exemplary embodiment of a plasma generation system, which comprises a HF generator, an impedance matching circuit, a plasma state monitoring device and a plasma chamber, according to some embodiments;

FIG. 2A and FIG. 2B show different exemplary embodiments of an impedance matching circuit;

FIG. 3 shows one exemplary embodiment of a measuring unit;

FIG. 4 shows a representation of a first diagram and a second diagram with time-varying measured values, according to some embodiments;

FIG. 5 shows the representation according to FIG. 4 wherein, in the second diagram, a different time-varying measured value having at least one measured variable is selected, according to some embodiments;

FIG. 6 shows a representation of the first and second diagrams, wherein a region is plotted in the first diagram, according to some embodiments;

FIG. 7 shows the representation according to FIG. 6, wherein multiple time-varying measured values of the first group in the first diagram lie outside the region, according to some embodiments;

FIG. 8 shows a flow diagram, which describes a method for monitoring the plasma generation system, according to some embodiments; and

FIG. 9 shows one embodiment of a control unit, e.g. of a plasma state monitoring device, according to some embodiments.

### DETAILED DESCRIPTION

Embodiments of the present invention provide a facility, by means of which operating personnel of a plasma generation system can identify an unwanted plasma state in a highly rapid and reliable manner, in order to enable the implementation of countermeasures in response to this information.

The plasma state monitoring device according to embodiments of the invention is employed for connecting to an impedance matching circuit for a plasma generation system. The impedance matching circuit can also be described as a “matchbox”. The plasma state monitoring device is configured to capture a first group of time-varying measured values. Time-varying measured values in the first group are dependent upon the impedance which is detectable on one of the terminals (for example, the input terminal or output terminal) of the impedance matching circuit, and are recorded in a temporally sequential manner. Time-varying measured values in the first group preferably relate to impedance. Time-varying measured values in the first group can also comprise a reflection factor, which is dependent upon impedance. The term “recorded” is understood to include both a measurement and a calculation. The plasma state monitoring device is further configured to capture time-varying measured values of at least one measured variable of a second group. The at least one measured variable is selected from a voltage, a current, or a phase relationship between current and voltage. Time-varying measured values of the respective measured variable are also recorded in a temporally sequential manner. Preferably at least two, and further preferably all three measured variables are selected. Further preferably, the second group comprises an equal number of time-varying measured values for each measured variable. Thus, a hundred time-varying measured values for voltage can be provided. A hundred time-varying measured values for current can be provided. A hundred time-varying measured values for the phase relationship between current and voltage can be provided. Preferably, only time-varying measured values of the respective measured variable are recorded in a temporally sequential manner. Thus, for example, the first time-varying measured value of voltage, the first time-varying measured value of current and the first time-varying measured value of the phase relationship can be recorded at the same time, or in a directly sequential manner, i.e. within a very narrow time-related focus. The respective second time-varying measured value of the measured variable is then temporally recorded subsequently to the respective first time-varying measured value of the same measured variable. The plasma state monitoring device is moreover configured to plot time-varying measured values of the first group in a first diagram. The first diagram is a diagram with no time axis, in particular a diagram for representing complex impedance or the reciprocal value thereof, the complex reflection factor and/or the reflected power in a complex form, preferably a Smith diagram. In this context, the term “complex” is the mathematical description of a numerical value having an actual component and a notional component. The plasma state monitoring device is further configured to plot time-varying measured values of the at least one measured variable of the second group in a second diagram. The second diagram can preferably be a diagram having two axes, wherein one axis is a time axis. Time-varying measured values in the first group and time-varying measured values of the respective measured variable in the second group have been at least partially or entirely captured within the same time period, as a result of which a state monitoring of the plasma generation system is enabled. By the term “partially within the same time period”, it is preferably to be understood that the first time-varying measured value in the first group and the first time-varying measured value of the at least one measured variable in the second group have been captured with a mutual temporal offset of less than 500 ms, 100 ms, or less than 50 ms. Operating personnel of the plasma generation system are thus enabled, in a highly graphic manner, to identify a dependence between a captured variable, e.g. impedance, and a captured measured variable, such as voltage, current and/or the phase relationship between current and voltage. By means of the parallel visualization of different installation parameters, it is directly made evident to operating personnel whether or not a permissible plasma state is in force. As a result, operating personnel can intervene in the control of the plasma generation system in a highly rapid manner. Were only the impedance to be indicated, it is possible that unwanted plasma states would not be detected, or not promptly detected. By the additional representation of at least one further measured variable, operating personnel are able to directly conclude whether this further measured variable and the captured impedance are consistent with the desired plasma state or otherwise. In this manner, major damage, e.g. to semiconductor products which are produced by the plasma process, can be reduced or prevented.

In an advantageous further development, an output device is provided. The plasma state monitoring device is configured to enable the simultaneous visibility of the first diagram and the second diagram to a viewer, and thus e.g. to execute the simultaneous representation thereof on the same output device. The output device can be a monitor. The output device can also comprise a web server only, which is retrieved by a computer and represented on a monitor.

In an advantageous further development, the plasma state monitoring device is configured to capture the first group of time-varying measured values and the second group of time-varying measured values of the at least one measured variable at a measuring point within the plasma generation system. It is particularly advantageous that the time-varying measured values of both groups are captured at the same measuring point. Particularly good comparability is enabled as a result.

In an advantageous further development, the measuring point is locatable in the region of an input terminal of the impedance matching circuit. Alternatively, the measuring point is locatable in the region of an output terminal of the impedance matching circuit. The input or output terminal can be, for example, plug-in connections on the housing of the impedance matching circuit. By the wording “in the region of”, it is particularly to be understood that the measuring point is locatable within a distance of less than 50 cm, 30 cm, or less than 10 cm from the input terminal or output terminal. The measuring point is preferably locatable externally to a housing of the impedance matching circuit. The measuring point can also be locatable within a housing of the impedance matching circuit.

In an advantageous further development, a measuring unit is provided. The measuring unit is configured to measure the second group of time-varying measured values in the form of the at least one measured variable, in particular in the form of multiple measured variables. The plasma state monitoring device can further be configured, from the measured time-varying measured values of the at least one measured variable (current, voltage and/or the phase relationship between current and voltage) of the second group, to calculate the first group of time-varying measured values. Preferably, a complex current and a complex voltage are measured, in order to enable a calculation herefrom of impedance, i.e. the time-varying measured values of the first group.

In an advantageous further development, the measuring unit is configured to measure the second group of time-varying measured values in the form of current and voltage, by way of measured variables. A complex value is thus ascertained, which is dependent upon measured values of current and voltage. In particular, the plasma state monitoring device can be configured to calculate the phase relationship from the measured current and the measured voltage. In each case, those time-varying measured values of current and voltage which have been measured simultaneously, or in the closest possible temporal proximity, can be mutually offset. Preferably, a phase value is calculated for each measured value of current and for each measured value of voltage. These three time-varying measured values of the three measured variables can then be plotted in the second diagram. In this context, it is particularly advantageous if only the measurement of current and voltage are actually required.

In an advantageous further development, the measuring unit comprises a directional coupler. By means of this directional coupler, for example, power ratings of the incoming and outgoing wave can be measured. The power measurement of forward power can thus be considered in relation to the incoming wave. The power measurement of reflected power can thus be considered in relation to the incoming wave. As an alternative to a directional coupler, the measuring unit can comprise a current sensor and a voltage sensor.

In an advantageous further development, the measuring unit comprises a digitization device, particularly in the form of an A/D converter (analog/digital converter). The digitization device is configured to digitize the second group of time-varying measured values of the at least one measured variable. The digitization device preferably has a sampling rate in excess of 50 kHz. The sampling rate can preferably exceed 0.5 MS/s (megasamples per second), 1 MS/s, 10 MS/s or 100 MS/s. It is thus ensured that even rapid variations of the time-varying measured value in the first group can be captured. In particular, the digitization device is configured to digitize time-varying measured values of current and time-varying measured values of voltage in a simultaneous or directly sequential manner. In this case, the digitization device would comprise an A/D converter having at least two channels, or two A/D converters. The digitization device can moreover comprise a FPGA and/or DSP, in order to enable the further mathematical processing of digitized measured values.

In an advantageous further development, a memory device is provided. To this end, the digitization device is configured to save digitized time-varying measured values of the second group in the memory device. The memory device can be configured, for example, in the form of a ring buffer. The plasma state monitoring device in general, or the digitization device in particular, can also be configured to save the calculated phase relationship between current and voltage in the memory device. The same can also apply to time-varying measured values in the first group and thus, in particular, to impedance.

In an advantageous further development, the plasma state monitoring device is configured to receive a trigger signal, particularly in the form of a pulse signal of a HF generator. The plasma state monitoring device can further be configured, in response to the presence of such a trigger signal, to capture the first group of time-varying measured values and the second group of time-varying measured values of the at least one measured variable. Time-varying measured values are preferably captured for a specific time period, or are captured continuously, and can be designed for representation in the first and second diagram. This capture for a specific time period, or continuous capture, can also include saving in the memory device. In the event of continuous capture, the memory device, immediately it is completely full, can be overwritten again from the start. A memory device in the form of a ring buffer is thus particularly advantageous. The plasma state monitoring device is preferably configured for triggering on a rising edge of the pulse signal of the HF generator. In principle, the plasma state monitoring device can also be triggered on a falling edge.

In an advantageous further development, the plasma state monitoring device is configured to progressively capture new measured values of the first group and second group, and to execute the representation thereof in the first and second diagram, as a result of which the first and second diagram are progressively updated.

In an advantageous further development, the plasma state monitoring device is configured, upon each reception of a trigger signal, to capture a specific number of measured values in the first and second group, and to execute the respective plotting thereof in the first and second diagram. In the event of a periodic trigger signal, a progressive updating of the first and second diagrams with present measured values in the first and the second group can thus be executed. By the term “plotting in a diagram”, it is signified that the plasma state monitoring device is designed to communicate the corresponding values to an output device, such that the latter is enabled to execute the corresponding representation thereof.

In an advantageous further development, the number of time-varying measured values in the first group corresponds to the number of time-varying measured values of the respective measured variable in the second group, or deviates therefrom by a maximum of 10%. Thus, for example, a hundred time-varying measured values of impedance can be provided and, preferably, a hundred time-varying measured values of current, a hundred time-varying measured values of voltage and, for example, a hundred time-varying measured values of the phase relationship between current and voltage can also be provided. As a result, a contrast and comparison of individual measured values is enabled in a particularly simple manner.

In an advantageous further development, the plasma state monitoring device is configured to plot at least a number, or all of the time-varying measured values in the first group in the first diagram by varying means of expression, in particular by colors. These means of expression thus indicate time points at which time-varying measured values in the first group have been captured. It is thus possible that, for example, a hundred time-varying measured values of impedance can be plotted in the first diagram in colors ranging from yellow to blue, depending upon the time point at which these measured values have been captured. Colors are also understood to include various shades of gray. A further option for expression, for example, is the representation of a number or all of the time-varying measured values in the first diagram with a different cross-hatching. Operating personnel are thus provided with a direct overview of the sequence in which the first measured values have been captured. This applies in particular, wherein the first diagram is preferably a diagram having no time axis, e.g. a Smith diagram, in which measured values of the first group are plotted.

In an advantageous further development, the plasma state monitoring device is configured to plot time-varying measured values of the first group in the first diagram with a characteristic for the expression thereof, in particular a color characteristic (which also includes shades of gray), wherein the expression characteristic is selected such that time-varying measured values in the first group which have been captured previously are represented in a darker shade than time-varying measured values in the first group which have been captured subsequently. Time-varying measured values in the first group which are captured subsequently are represented in a lighter shade. An inverse arrangement can also apply.

In an advantageous further development, the first axis of the second diagram is the measured value axis, and the second axis of the second diagram is the time axis. Preferably, the time axis is the x-axis and the measured value axis is the y-axis.

In an advantageous further development, an input unit is provided, and is configured to capture a user input. The input unit can comprise a mouse, a keyboard and/or a touchscreen. In principle, an input unit can be any device which is appropriate for moving or positioning a pointer, in particular a mouse pointer, a cursor or a marker on a screen in a targeted manner.

In an advantageous further development, the plasma state monitoring device is configured to determine, by means of the input unit, which time-varying second measured value in the first or second diagram is selected by a user. The plasma state monitoring device is then configured to optically highlight the time-varying measured value in the other diagram which has been captured within the same time period as the selected time-varying measured value. In the event that the user selects the hundredth time-varying measured value in the form of an impedance in the first group, the plasma state monitoring device is configured to highlight the hundredth time-varying measured value of the respective measured variable in the second group. The plasma state monitoring device can thus highlight the hundredth time-varying measured value for voltage, for current and/or for the phase relationship between current and voltage. Conversely, the plasma state monitoring device, in the event that, for example, the fiftieth time-varying measured value for voltage in the second group has been selected, can highlight the fiftieth time-varying measured value for impedance in the first group. Optical highlighting can be executed, for example, by means of an enlarged representation of the respective measured value. The addition of a border is also conceivable.

In an advantageous further development, the plasma state monitoring device is configured to determine which of the plotted time-varying measured values in the first group has been selected by the user in the first diagram, by means of the input unit.

In an advantageous further development, the plasma state monitoring device is configured to optically highlight the selected time-varying measured value of the first group in the first diagram, in particular by the enlarged representation thereof and/or by the representation thereof with a border.

In an advantageous further development, the plasma state monitoring device is configured to optically highlight time-varying measured values of the respective measured variable in the second group which are plotted in the second diagram and which have been captured in the same time period as the selected time-varying measured value of the first group.

In an advantageous further development, the plasma state monitoring device is configured to optically highlight time-varying measured values of the respective measured variable in the second group, by means of an enlarged representation and/or by means of a border. Additionally or alternatively, the plasma state monitoring device is configured to displace or plot in a corresponding marking line at the location of the respective measured value for the corresponding measured variable (current, voltage and/or phase relationship) of the second group, in the interests of the optical highlighting thereof.

In an advantageous further development, the plasma state monitoring device is configured to determine which of the plotted time-varying measured values of the respective measured variable (current, voltage and/or phase relationship) in the second group is selected by the user in the second diagram, by means of the input unit.

In an advantageous further development, the plasma state monitoring device is configured to determine a displacement of a marking line and/or of a cursor along the time axis in the second diagram, which is executed by the user by means of the input unit. Additionally or alternatively, the plasma state monitoring device is configured to determine a marking of a point and/or of a region in the second diagram which is executed by the user by means of the input unit. The plasma state monitoring device can thus determine which of the plotted time-varying measured values of the respective measured variable in the second group is selected in the second diagram.

In an advantageous further development, the plasma state monitoring device is configured to optically highlight time-varying measured values in the first group (in particular by the expressive representation thereof) which are plotted in the first diagram and which have been captured in the same time period as the selected time-varying measured value of at least one measured variable (voltage, current and/or phase relationship) in the second group.

In an advantageous further development, the plasma state monitoring device is configured to plot a region in the first diagram. The plasma state monitoring device is further configured to highlight those time-varying measured values of the first group in the first diagram which lie outside this region. Additionally or alternatively, the plasma state monitoring device is configured to optically highlight those time-varying measured values of the at least one measured variable of the second group in the second diagram which have been captured in the same time period as those time-varying measured values of the first group which lie outside this region. Reliable impedance ranges can thus be defined in a particularly advantageous manner. In the event that time-varying measured values in the first group (impedance target values) lie outside this region, time-varying measured values of the second group which correspond to these time-varying measured values in the first group can also be highlighted. It is thus directly evident to the user whether or not a desired plasma state has been achieved.

In an advantageous further development, the plasma state monitoring device is configured to optically highlight time-varying measured values of the at least one measured variable in the second group, wherein an enlarged representation thereof and/or a representation thereof with a border is executed, and/or wherein the representation thereof is executed by a different expression, in particular with respect to color, and/or wherein a marking is added in direct proximity to the respective time-varying measured value of the at least one measured variable in the second group.

In an advantageous further development, the plasma state monitoring device is configured to output an alarm, in the event that time-varying measured values of the first group in the first diagram lie outside this region. The alarm can be executed acoustically and/or optically. Additionally or alternatively, it is also possible that these time-varying measured values of the first group, and the time-varying measured values of the at least one measured variable in the second group which correspond thereto, are permanently saved in a memory device. In this case, a more detailed subsequent evaluation will still be enabled. Additionally or alternatively, it is also possible that the plasma state monitoring device is configured to switch off the HF generator or to reduce the output power thereof.

In an advantageous further development, the plasma state monitoring device is configured to plot a further region in the first diagram. The plasma state monitoring device can further be configured to switch off the HF generator, or to influence the output power thereof, e.g. by way of a reduction, in the event that a time-varying measured value in the first group or a specific number of time-varying measured values in the first group lie outside this further region.

In an advantageous further development, the plasma state monitoring device is configured to define this region by reference to a user input which is executed via the input device. The user can thus indicate or input that region within which time-varying measured values in the first group (particularly impedance) are considered as reliable.

The plasma state monitoring device can optionally save various regions for different plasma processes in a memory device.

In an advantageous further development, the plasma state monitoring device is configured to progressively capture time-varying measured values of the first group and time-varying measured values of the second group, and to execute the plotting thereof in the respective first and second diagram.

In an advantageous further development, the plasma state monitoring device is configured to form time-varying measured values of the first group and time-varying measured values for the at least one measured variable of the second group from averaged individual measured values. Accordingly, time-varying measured values which are plotted in the first and second diagram can also be comprised of, or can incorporate average values.

In an advantageous further development, the plasma state monitoring device is configured to capture time-varying measured values of a third and group and, preferably, time-varying measured values of a fourth group. The plasma state monitoring device can be further configured to represent the third group in a third diagram and, preferably, to represent the fourth group in a fourth diagram. Preferably, time-varying measured values in the third group and/or in the fourth group are recorded at a different measuring point from time-varying measured values in the first and second group. Time-varying measured values in the second group can preferably be impedance values. Time-varying measured values in the fourth group can preferably comprise at least one measured variable which is selected from a voltage, a current and/or a phase relationship between voltage and current. The third diagram can be a diagram with no time axis, in particular a Smith diagram. The fourth diagram can comprise two axes, one of which axes is a time axis. Preferably, all the above-mentioned statements with respect to the first and second group are also applicable to the third group and, in particular, to the fourth group.

The plasma system according to embodiments of the invention comprises the above-mentioned plasma state monitoring device. Moreover, an impedance matching circuit, a HF generator and, in particular, at least one load, preferably in the form of a plasma chamber, are provided. The HF generator is connected to the HF input of the impedance matching circuit. The HF output of the impedance matching circuit is connectable to and, in particular, is connected to the at least one load. The first group of time-varying measured values can be captured at the HF input of the impedance matching circuit. The second group of time-varying measured values of the at least one measured variable can also be captured at the HF input of the impedance matching circuit.

The method according to embodiments of the invention is employed for monitoring the plasma generation system by means of a plasma state monitoring device for connecting to an impedance matching circuit. The plasma state monitoring device can be configured to execute the following process steps:
a) Capture of a first group of time-varying measured values, wherein time-varying measured values in the first group are dependent upon the impedance which is detectable on one of the terminals of the impedance matching circuit, and are recorded in a temporally sequential manner;
b) Capture of second group of time-varying measured values of at least one measured variable, wherein the at least one measured variable is selected from:
   i) voltage;
   ii) current;
   iii) the phase relationship between current and voltage;
   wherein time-varying measured values of the respective measured variable are recorded in a temporally sequential manner;
c) Representation of the first group in a first diagram, wherein the first diagram is a diagram with no time axis, in particular a Smith diagram, and representation of the second group in a second diagram, wherein the second diagram comprises two axes, of which one axis is a time axis, wherein time-varying measured values in the first group and time-varying measured values of the respective measured variable in the second group have been captured within an at least partially identical time period, as a result of which a state monitoring of the plasma generation system is enabled.

Various exemplary embodiments of the invention are described hereinafter with reference to the drawings. Identical objects are identified by the same reference numbers.

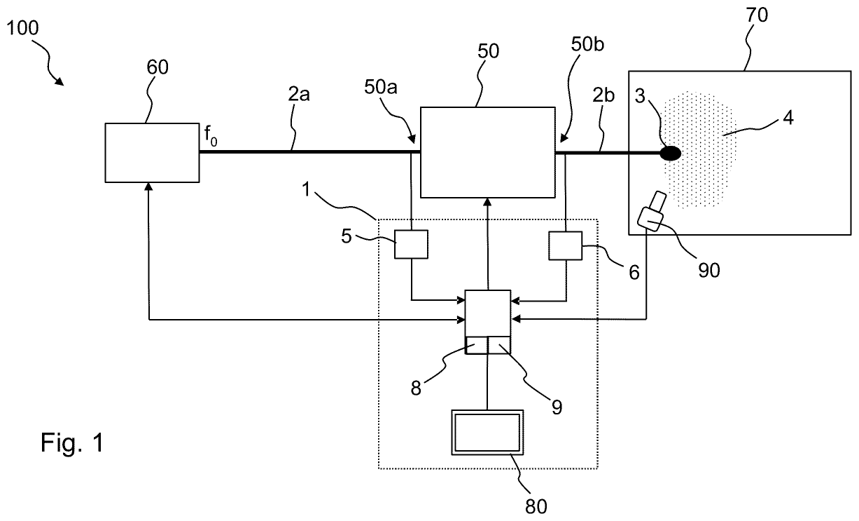

FIG. 1 shows a plasma generation system 100 which is employed, inter alia, for the surface treatment of workpieces. In addition to the processing of surfaces by plasma processes, the plasma generation system 100 can also be employed in semiconductor production processes, or for the laser excitation of gas lasers, e.g. CO₂ gas lasers.

The plasma generation system 100 comprises a plasma state monitoring device 1, an impedance matching circuit 50, a HF generator 60 and a plasma chamber 70 (load). The HF generator 60 is electrically connected to the impedance matching circuit 50. This is executed by means of a cable connection 2a, which preferably comprises a first cable connection 2a, in particular at least one first coaxial cable 2a. The first cable connection 2a is connected to an output terminal 60a of the HF generator 60 and to an input terminal 50a of the impedance matching circuit 50. The impedance matching circuit 50 is further electrically connected to the plasma chamber 70. This is preferably executed by means of a further, in particular a second cable connection 2b, which preferably comprises a second coaxial cable 2b. In many cases, the impedance matching circuit 50 is arranged close to the plasma chamber 70, in particular at a distance of 10 cm or less than 10 cm, and is preferably arranged in direct proximity thereto, such that the second cable connection 2b is also configured with a correspondingly short length, and comprises only a limited number of mechanical parts, such as e.g. plugs and/or line connectors. The second cable connection 2b is connected to an output terminal 50b of the impedance matching circuit 50, and to an input of the plasma chamber 70. The second cable connection 2b is preferably connected to an electrode within the plasma chamber 70.

The first cable connection 2a is longer than the second cable connection 2b. The first cable connection 2a is preferably longer than the second cable connection 2b by a factor of 2, 3, 4, 5, 6, 7, or at least by a factor of 8.

The plasma generation system 100 preferably comprises an output device 80, which is preferably a screen. An input unit 9 is also provided. The input unit 9 is appropriate for the targeted movement of a cursor or marker on the output device 80. The input unit 9 can comprise, for example, a keypad and/or a mouse. A touchscreen can also be considered as an input unit 9.

The plasma chamber 70 can be considered as a load (consuming device). Depending upon the application, for example, one or more electrodes can be provided in the plasma chamber 70, at least one of which is connected to the second cable connection 2b. In FIG. 1, a plasma 4 within the plasma chamber is represented by dots.

The plasma generation system 100 further comprises an optical device 90. Further preferably, the optical device 90 is arranged in the plasma chamber 70, and is configured for the visual capture of the plasma 4, and thus of the plasma state. The optical device 90 can comprise, for example, an optical conductor such as, for example, a glass fiber. Although cameras can be employed, the employment thereof is frequently waived on the grounds of cost. Moreover, lenses and other protective glass elements can be rapidly clouded by the plasma 4.

In particular, the plasma state monitoring device 1 is described in greater detail hereinafter. The plasma state monitoring device 1 preferably comprises at least one processor (for example, a microcontroller) and/or a programmable logic module, e.g. a FPGA (field programmable gate array).

According to one exemplary embodiment, the plasma state monitoring device 1 can be employed, for example, for actuating the impedance matching circuit 50. The plasma state monitoring device 1 can thus be configured to actuate the impedance matching circuit 50, such that the latter sets a specific impedance target value.

In FIG. 1, the input terminal 50a of the impedance matching circuit 50 is illustrated directly on the housing of the impedance matching circuit 50. In principle, the location thereof at the end of the first cable connection 2a at which the first cable connection 2a is connected to the HF generator 60 is also possible. Consideration of the cable impedance of the first cable connection 2a is also included as a result.

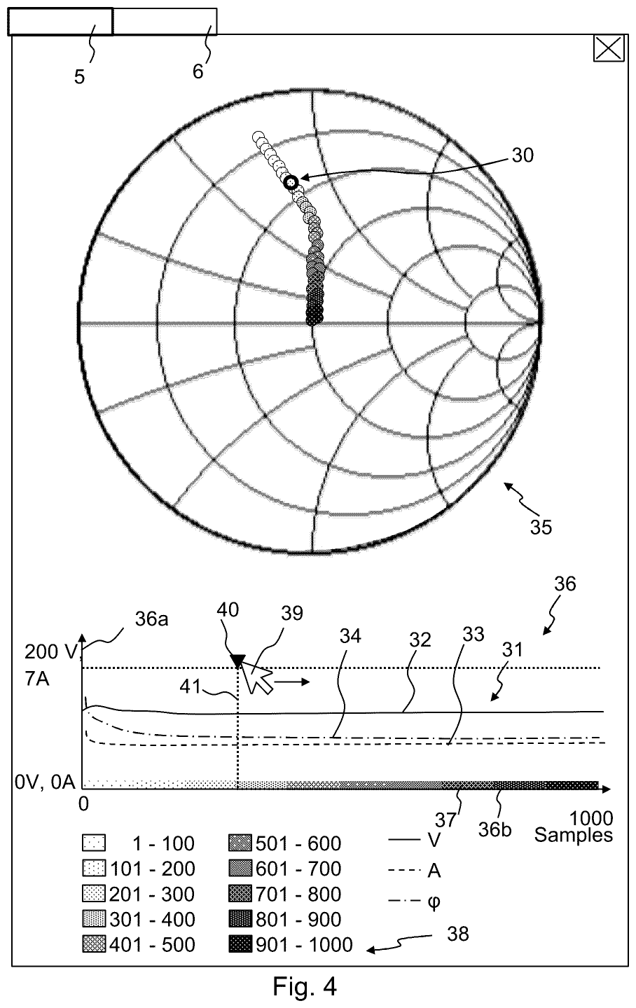

According to the invention, the plasma state monitoring device 1 is configured for capturing a first group of time-varying measured values 30, wherein the time-varying measured values 30 in the first group are dependent upon the impedance which is detectable on the input terminal 50a of the input matching circuit 50 or on the output terminal 50b of the impedance matching circuit 50. The plasma state monitoring device 1 can also be employed for capturing a second group of time-varying measured values 31 of at least one measured variable, wherein the at least one measured variable is selected from a voltage 32, a current 33 and a phase relationship 34 between voltage 32 and current 33. As described in detail hereinafter with reference to FIG. 4 and onwards, the plasma state monitoring device 1 can further be configured to represent the first group in a first diagram 35, wherein the first diagram 35 can preferably be a Smith diagram. The plasma state monitoring device 1 can moreover be configured to represent the second group in a second diagram 36, wherein the second diagram 36, in particular, can comprise two axes 36a, 36b, wherein one axis can preferably be a time axis.

The plasma state monitoring device 1 comprises at least one measuring unit 5. Time-varying measured values 31 having the at least one measured variable 32, 33, 34 of the second group can be measured by the at least one measuring unit 5.

The at least one measuring unit 5 is preferably arranged between the first cable connection 2a and the impedance matching circuit 50. In this case, a further measuring unit 6 is arranged between the impedance matching circuit 50 and the load 70.

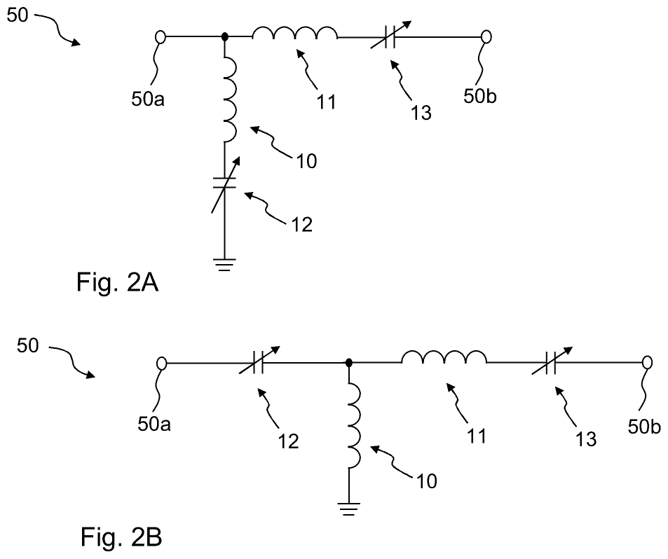

FIGS. 2A, 2B show different exemplary embodiments of the impedance matching circuit 50. In FIG. 2A, the impedance matching circuit 50 is L-shaped. In FIG. 2B, the impedance matching circuit 50 is T-shaped.

The input terminal 50a of the impedance matching circuit 50 in FIG. 2A is connected to a first coil 10 (first inductance) and to a second coil 11 (second inductance). The first and second coils 10, 11, at their first terminal, are arranged on a common node, and thus at the input terminal 50a of the impedance matching circuit 50. The first coil 10 is connected via a first capacitor 12 (first capacitance) to a reference ground. The second coil 11 is connected to the output terminal 50b via a second capacitor 13 (second capacitance). The first and second capacitors 12, 13 are adjustable components, particularly in the form of rotary capacitors, the capacitance of which can be varied by means of stepper motors. Alternatively, solid state switches can be employed, in order to enable the most rapid possible switch-in and switch-out of capacitances. In particular, the plate spacing of the first and second capacitors 12, 13 can be varied. According to one exemplary embodiment, the plasma state monitoring device 1 can be configured to correspondingly actuate the respective stepper motors. In principle, actuation can also be executed by a control device. The capacitances of the first and second capacitors 12, 13 can be adjusted in a mutually independent manner. The impedance matching circuit 50 is preferably free of further components. Naturally, the position of the first coil 10 and of the first capacitor 12 can also be interchanged. In this case, the first capacitor 12 is arranged on the input terminal 50a of the impedance matching circuit 50, and the first coil 10 is arranged on the reference ground. Additionally or alternatively, the position of the second coil 11 and of the second capacitor 13 can also be interchanged. In this case, the second capacitor 13 is arranged on the input terminal 50a of the impedance matching circuit 50, and the second coil 11 is arranged on the reference ground.

In FIG. 2B, the input terminal 50a of the impedance matching circuit 50 is connected to the first capacitor 12 (first capacitance). The first capacitor 12 is connected both to the first coil 10 (first inductance) and to the second coil 11 (second inductance). This is executed by means of a common node, to which both the first capacitor 12 and the first and second coils 10, 11 are connected. The first coil 10 is further connected to the reference ground. The second coil 11 is connected to the second capacitor 13 (second capacitance) (in a series circuit). The second capacitor 13 is connected to the output terminal 50b of the impedance matching circuit 50. The position of the second coil 11 and of the second capacitor 13 can also be interchanged. In this case, the second capacitor 13 would be connected to the common node, and the second coil 11 would be connected to the output terminal 50b of the impedance matching circuit 50. The impedance matching circuit 50 is preferably free of further components.

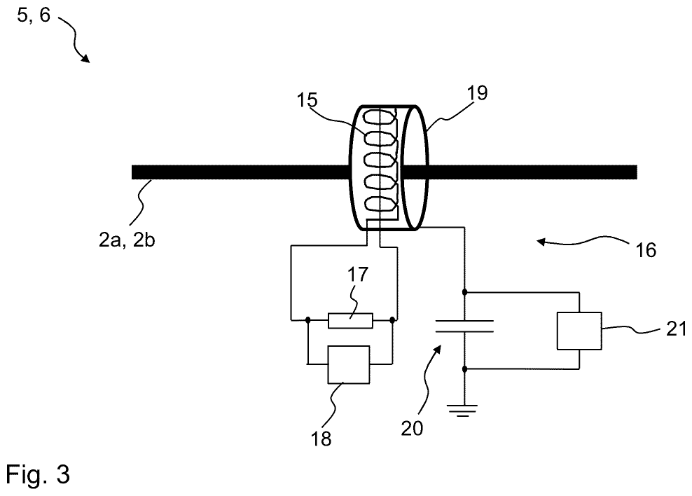

FIG. 3 shows an exemplary embodiment of one potential layout of the measuring unit 5 or of the further measuring unit 6. In this exemplary embodiment, the measuring units 5, 6 are configured for a contactless measurement of a voltage and for a contactless measurement of a current.

To this end, the respective measuring unit 5, 6 comprises a current sensor 15 and a voltage sensor 16.

Preferably, however, the phase relationship between current and voltage is further measured, such that the impedance, and thus the time-varying measured values 30 of the first group can be calculated.

The current sensor 15 of the measuring unit 5 and/or of the further measuring unit 6 is configured as a coil, particularly in the form of a Rogowski coil.

Both ends of the coil are preferably interconnected via a shunt resistor 17. The voltage which drops across the shunt resistor 17 can be digitized by means of a first A/D converter 18. The first A/D converter 18 would be an element of a digitization device.

The voltage sensor 16 of the measuring unit 5 and/or of the further measuring unit 6 is preferably configured as a capacitive voltage divider. A first capacitance 19 is formed by an electrically conductive ring 19. An electrically conductive cylinder can also be employed. The corresponding first or second cable connection 2a, 2b is led through this electrically conductive ring 19. A second capacitance 20 of the voltage sensor 16, which is configured as a voltage divider, is connected to the reference ground. A second A/D converter 21 is connected in parallel with the second capacitance 20, which is configured to capture and digitize the voltage which drops across the second capacitance 20. The second A/D converter 21 would be an element of a digitization device.

In principle, the measuring unit 5 and the further measuring unit 6 can also be arranged or configured on a (common) circuit board. The first capacitance 19 can be formed by a coating on a first side and on the opposing second side of the circuit board. In this case, coatings on the first and second sides are electrically interconnected by means of through-contacts. The first or second cable connection 2a, 2b is led through an opening in the circuit board. The second capacitance 20 can be formed by a discrete component.

The current sensor 15 in the form of the coil, particularly in the form of the Rogowski coil, is further spaced from the first or second cable connection 2a, 2b than the first capacitance 19. The coil can also be formed on the same circuit board, by means of corresponding coatings, together with through-contacts. The coil for current measurement and the first capacitance for voltage measurement are preferably oriented in a common plane.

The shunt resistor 17 can also be arranged on this circuit board. The same also applies to the first and/or second A/D converter (analog/digital converter) 18, 21.

The measuring unit 5 and/or the further measuring unit 6 can also be configured in the form of directional couplers.

FIG. 4 shows the first diagram 35 and the second diagram 36 for the measuring unit 5. The measuring unit 5 is preferably arranged at the input terminal 50a of the impedance matching circuit 50. In the event that the further measuring unit 6 is employed, which is preferably arranged at the output terminal 50b of the impedance matching circuit 50, the first diagram 35 and the second diagram 26 for the further measuring unit 6 can be selected by means of a corresponding slider.

As described, by means of the measuring unit 5, it is possible to measure a voltage 32 and a current 33. The plasma state monitoring device 1 is configured to ascertain the phase relationship 34 between the voltage 32 and the current 33 from the voltage 32 and the current 33. Preferably, a complex value can thus be ascertained, which is related to the complex impedance. This involves the respective measured variables of time-varying measured values 31 in the second group. The measuring unit 5 is configured for the sequential measurement of a multiplicity of time-varying measured values 31 of the voltage 32. This multiplicity of time-varying measured values 31 of the voltage 32 are plotted in the second diagram 36. The second axis 36b is a time axis for the representation of a thousand sequentially recorded time-varying measured values 31 for the respective measured variable of the second group. In the first axis 36a, the corresponding value for the respective measured variable is represented. In principle, the various measured variables, i.e. the voltage 32, the current 33 and the phase relationship 34 can be standardized. In the representation according to FIG. 4, a voltage 32 of 200 V and a current 33 of 7 A are present on the same point of the first axis 36a.

In particular, the plasma state monitoring device 1 is configured to progressively capture time-varying measured values 31 in the second group by means of the measuring unit 5. A represented measured value 31 for voltage 32, for example, can comprise a multiplicity of averaged voltage values. The same can also apply to the current 33 and the phase relationship 34.

The plasma state monitoring device 1 is preferably further configured to plot each newly captured or newly averaged measured value 31 for the respective measured variable of the second group in the second diagram 36. It would also be possible for new time-varying measured values 31 having the respective measured variable of the second group to be plotted in the second diagram 36, in the event that a specific number, for example a thousand measured values 31 for the respective measured variable, are available.

The plasma state monitoring device 1 is also configured, from the time-varying measured values 31 of the second group, to calculate time-varying measured values 30 of the first group. An impedance can thus be calculated from the (complex) voltage 32 and the (complex) current 33. It is self-evident that only such values for voltage 32 and current 33 will have been mutually offset as have been ascertained by the measuring unit 5 in the same time period. The plasma state monitoring device 1 is then configured to plot time-varying measured values 30 of the first group in the first diagram 35.

The number of time-varying measured values 30 of the first group which are plotted in the first diagram 35 is preferably identical to the number of time-varying measured values 31 of the respective measured variable in the second group which are plotted in the second diagram 36. Consequently, the exemplary embodiment preferably includes a thousand time-varying measured values 30 of the first group and, in each case, a thousand time-varying measured values 31 for voltage 32 current 33 and the phase relationship 34. Further to the common representation of the first diagram 35 and the second diagram 36 on the output device 80, it is very easy for a user to establish a connection between the impedances represented and the represented characteristic of voltage 32, current 33 and the phase relationship 34.

Preferably, the plasma state monitoring device 1 further comprises a memory device 8, in which time-varying measured values 30 of the first group and/or time-varying measured values 31 for the respective measured variable in the second group can be saved.

The plasma state monitoring device 1 is preferably configured to receive a trigger signal. A trigger signal of this type can be an edge of a pulse signal of the HF generator 60. Further to the detection of a trigger signal of this type, a predetermined number of time-varying measured values 30 of the first group and of time-varying measured values 31 having the respective measured variables of the second group are captured and represented on the output device 80 in the first or second diagram 35, 36.

In FIG. 4, it is also represented that the plasma state monitoring device 1 is configured to plot at least a number, or all of the time-varying measured values 30 of the first group in the first diagram 35 with different means of expression. These different means of expression are preferably different colors. However, different cross-hatchings can also be employed. Means of expression indicate time points at which time-varying measured values 31 of the first group have been captured. In FIG. 4, older time-varying measured values 31 of the first group are represented in a lighter shade than more recent time-varying measured values 31 of the first group.

Preferably, in FIG. 4, a first key 37 is also represented, which is plotted in the second diagram 36. The first key 37 is represented along the second axis 36b and contains an overview of the means of expression. The first key 37 thus varies along the second axis 36b (the time axis) from light to dark. As a result, from the first diagram 35, a particularly simple assignment of respective time-varying measured values 30 of the first group to the respective time-varying measured values 31 of the respective measured variable of the second group in the second diagram 36 is enabled. A user can immediately identify which time-varying measured value 30 of the first group corresponds to which time-varying measured value 31 of the second group.

Preferably, in FIG. 4, a second key 38 is also represented, which indicates the various means of expression, together with information as to which time-varying measured values 31 of the first group are described by the respective means of expression. In this case, the lightest means of expression is employed for the hundred oldest time-varying measured values 31. In this case, the darkest means of expression is employed for the hundred most recent time-varying measured values 31.

The plasma state monitoring device 1 is also configured, by means of the input unit 9, to establish which time-varying measured values 30, 31 of the first or second group have been selected by a user in the first or second diagram 35, 26. In FIG. 4, a pointer 39, particularly in the form of a mouse pointer 39, is represented. This pointer 39 can be moved by a user. This can be executed by means of the input unit 9. In FIG. 4, the user e.g. has clicked-on the second diagram 36. In this case, the plasma state monitoring device 1 is configured to plot a cursor 40 and/or a marking line 41, wherein the marking line 41 is positioned over the respective measured variable. In this case, the cursor 40 and the marking line 41 indicate a time point at which approximately the three hundredth time-varying measured value 31 of the second group is represented. By means of this marking line 41, the corresponding measured variable of time-varying measured values 31 in the second group is optically highlighted. The marking line 41 preferably assumes a parallel orientation to the first axis 36a. It is also conceivable for those measured variables (voltage 32, current 33 and/or the phase relationship 34) which are located at the position of the cursor 40 to be represented in an enlarged form and/or in a different color in the second diagram 36.

At the same time, the plasma state monitoring device 1 is configured to optically highlight that time-varying measured value 30 of the first group which is plotted in the first diagram 35 and which has been captured in the same time period as the selected time-varying measured values 31 of the second group. In FIG. 4, the corresponding time-varying measured value 30 is highlighted by a border.

In principle, it would also be possible for the user to click-on the first diagram 35, and to select one of the plotted time-varying measured values 30 in the latter. The plasma state monitoring device 1 is then configured to optically highlight measured variables of the time-varying measured values 31 which correspond thereto in the second diagram 36. This can be executed, for example, by the displacement or overlaying of the marking line 41. Additionally or alternatively, a cursor 40 can also be displaced or overlaid at the corresponding location in the time axis (the second axis 36b). The respective measured variables, additionally or alternatively, can also be enlarged and/or represented by different colors in the second diagram 36.

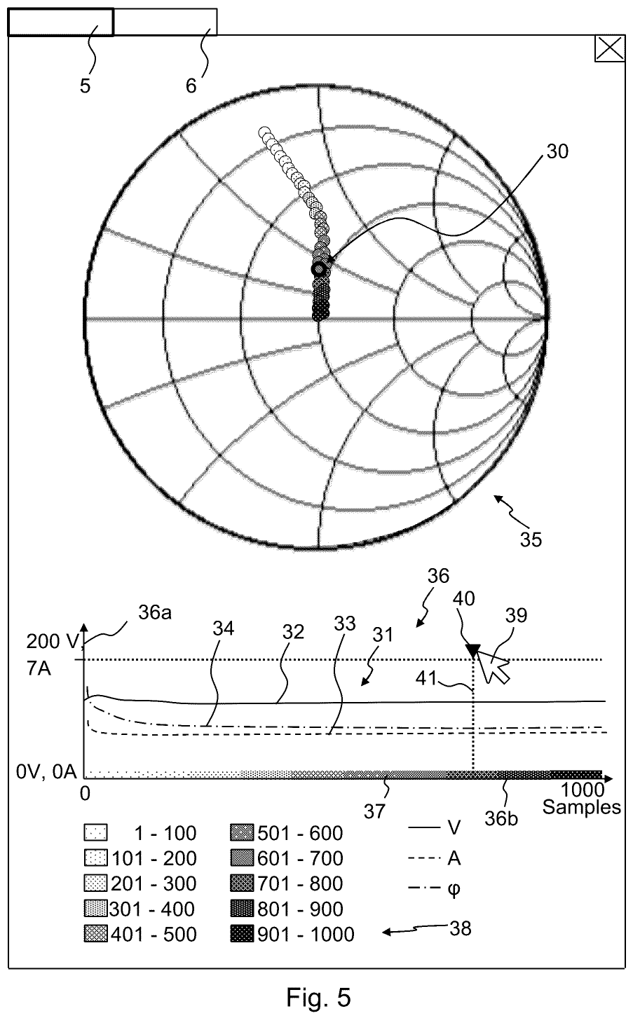

In FIG. 5, it is represented that the user marks different time-varying measured values 31 of the measured variables of voltage 32, current 33 and the phase relationship 34. This can be executed by displacing the cursor 40 and/or the marking line 41 according to FIG. 4. Thus, for example, the user can click-on the cursor 40 and/or the marking line 41 and execute the displacement thereof along the time axis (the second axis 36b). A movement of this type is indicated by the direction of the arrow in FIG. 4. To this end, the user can employ the mouse and/or the keypad. By means of a simple keypad input, it would also be conceivable for the user to skip to different time points on the time axis (the second axis 36b). Additionally, by clicking-on a different time point in the second diagram 36, different time-varying measured values 31, 30 in the second and first diagram 36, 35 can be selected. The plasma state monitoring device 1 is configured to optically highlight a different time-varying measured value 30 of the first group in the first diagram 35. This different time-varying measured value 30 has been recorded in the same time period as the correspondingly selected time-varying measured values 31 in the second diagram 36.

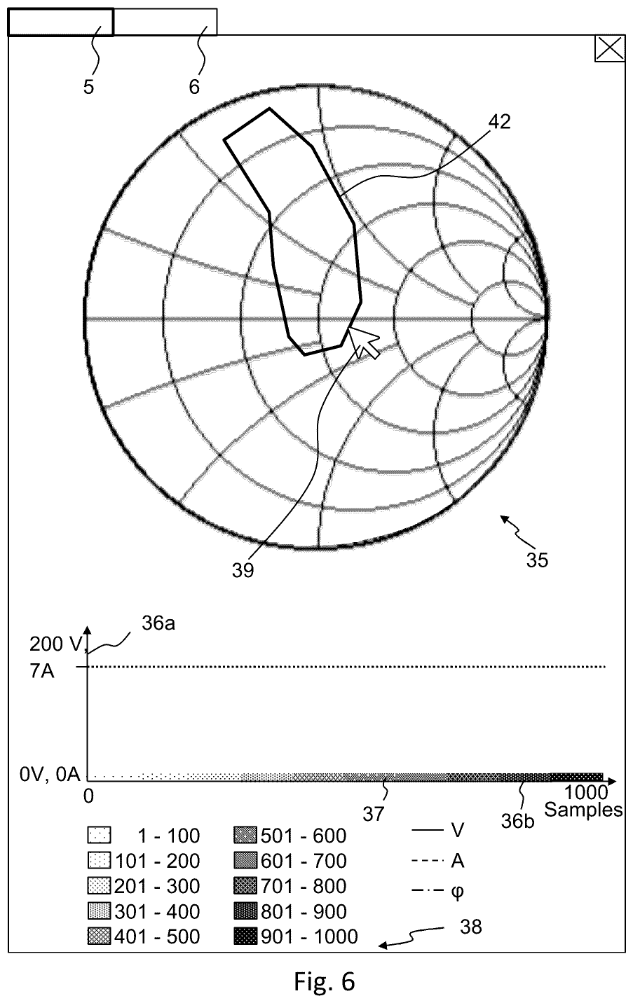

In FIG. 6, it is represented that the plasma state monitoring device 1 is configured to plot a region 42 in the first diagram 35. This plotting of a region 42 can be executed by moving a mouse. The corresponding vertices can be set, for example, by clicking. The region 42 can also be downloaded from the memory device 8. Depending upon the plasma process, different regions 42 can be defined. Impedances which lie within the region 42 are considered as permissible impedances.

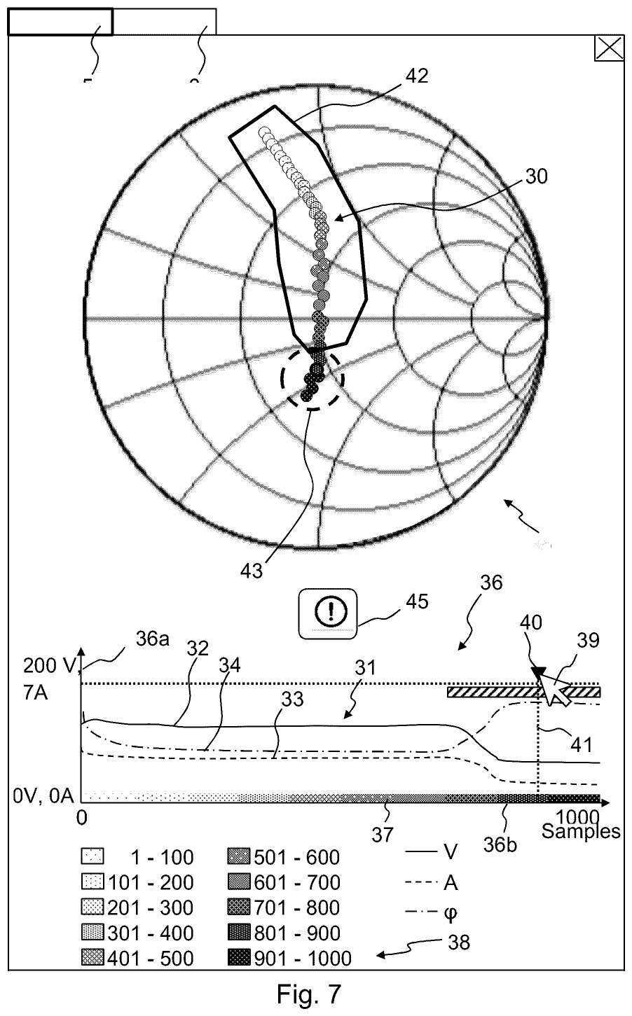

The plasma state monitoring device 1 is configured to optically highlight those time-varying measured values 30 of the first group in the first diagram 35 which lie outside this region 42. This subject matter is represented in FIG. 7. This optical highlighting can be executed by the selection of a different color, size and/or border for those time-varying measured values 30 of the first group which lie outside the region 42. It is also possible that an additional region 43 is plotted, in which those time-varying measured values 30 of the first group are included which lie outside the region 42. One or more such additional regions 43 can be provided.

In this context, the plasma state monitoring device 1 can also be configured to optically highlight time-varying measured values 31 of the respective measured variable of the second group in the second diagram 36 which have been recorded in the same time period as those time-varying measured values 30 of the first group in the first diagram 35 which lie outside the region 42. In FIG. 7, this optical highlighting is executed by means of a corresponding bar 44. The bar 44 extends in a parallel direction to the second axis 36b (the time axis), and encompasses those regions in which time-varying measured values 31 of the second group lie, the corresponding time-varying measured values 30 of which in the first group lie outside the region 42. One or more such bars 44 can be provided.

The plasma state monitoring device 1 can also be configured, in the event that time-varying measured values 30 of the first group lie outside the region 42, to save these time-varying measured values 30, or all the time-varying measured values 30 of the first group which have been recorded within a specific time window, in the memory device 8. In this context, preferably, time-varying measured values 31 of the at least one measured variable of the second group are also saved in the memory device 8.

Preferably, the plasma state monitoring device 1 is also configured to output a warning signal 45. In the present case, this is an optical warning signal on the output device 80. Additionally or alternatively, an acoustic warning signal can also be provided. The plasma state monitoring device 1 can also be configured to switch off the HF generator 60, or to influence the output power thereof, particularly by way of a reduction.

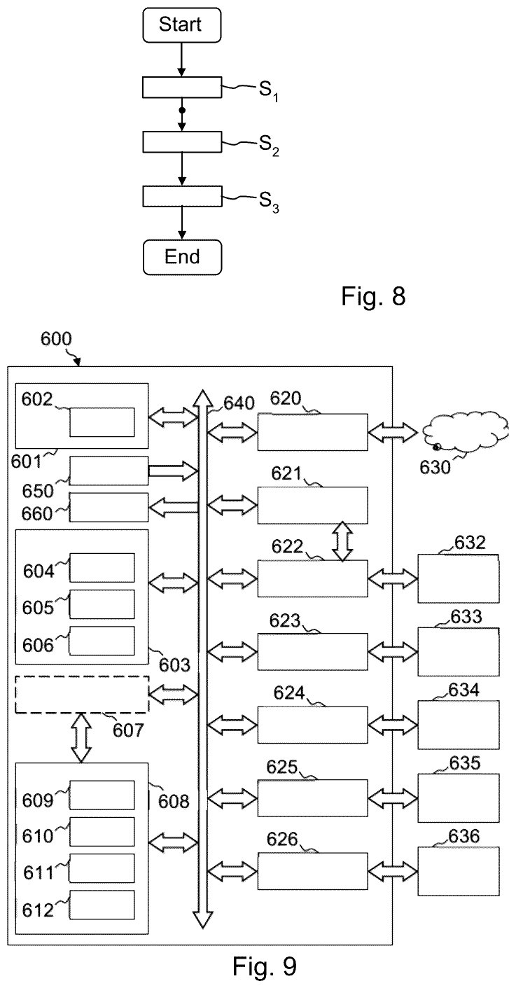

FIG. 8 shows a flow diagram which describes a method for monitoring a plasma generation system 100 by means of the plasm state monitoring device 1. In a first process step S₁, a first group of time-varying measured values 30 is captured, wherein time-varying measured values 30 in the first group are dependent upon the impedance which is detectable on the input terminal 50a or output terminal 50b of the impedance matching circuit 50, and are recorded in a temporally sequential manner. In a second process step S₂, a second group of time-varying measured values 31 of at least one measured variable (voltage 32, current 33 and the phase relationship 34) is captured, wherein time-varying measured values 31 of the respective measured variable are recorded in a temporally sequential manner. In a third process step S₃, the first group is represented in a first diagram 35, wherein the first diagram 35 is a diagram with no time axis, in particular a Smith diagram. The second group is represented in a second diagram 36, wherein the second diagram 36 comprises two axes 36a, 36b, of which one axis 36b is a time axis. Time-varying measured values 30 in the first group and time-varying measured values 31 of the respective measured variable in the second group have been captured within an at least partially identical time period. A particularly effective state monitoring of the plasma generation system 100 is thus enabled for the user.

FIG. 9 shows a schematic representation of one embodiment of a control unit 600, described hereinafter as a “control system” 600, which is appropriate for executing instructions for the execution of one or more aspects of the method in a device according to the present invention. For example, the control system 600 can be employed for the embodiment of the above-mentioned method and/or of a plasma state monitoring device 1 according to the invention and/or according to the preceding description. The components in FIG. 9 are to be understood as exemplary, and do not limit the scope of application or the functionality of hardware, software, firmware, embedded logic components, or a combination of multiple components of this type for the implementation of specific embodiments of the present invention. Some or all of the components represented can constitute an element of the control system 600.

In the present embodiment, the control system 600 comprises at least one processor 601 such as, for example, a central processing unit (CPU, DSP) or a programmable logic module (PLD, FPGA). The control system 600 can also comprise a working memory 603 and a data memory 608 which communicate with one another, and with other components, via a bus 640. The bus 640 can also connect a display 632, one or more input devices 633, one or more output devices 634, one or more memory devices 635 and various storage media 636 to one another and to one or more devices of the processor 601, the working memory 603 and the data memory 608. All these elements can be coupled to the bus 640, either directly or via one or more interfaces 622, 623, 624, 625, 626 or adapters.

The control system 600 can assume any appropriate physical form, including, but not by way of limitation, one or more integrated circuits (ICs), printed circuit boards (PCBs), portable terminals, laptop or notebook computers, distributed computer systems, computing grids or servers. The processor 601 or a central processing unit (CPU) optionally incorporates a cache memory unit 602 for the short-term local storage of commands, data or processor addresses. The processor 601 is configured to support the execution of instructions which are saved on at least one storage medium.

The memory 603, 608 can comprise various components, including, but not by way of limitation, a direct access memory component, e.g. a RAM 604, in particular a static RAM “SRAM”, a dynamic RAM “DRAM”, etc., a read-only component, e.g. a ROM 605, and arbitrary combinations thereof. The ROM 605 can also function for the unidirectional communication of data and instructions to the processor(s) 601, and the RAM 604 can also function for the bidirectional communication of data and instructions to the processor(s) 601.

The memory device 8 can be configured as an element of, or in the form of a memory 603, 608 of this type.

The read-only memory 608 is bidirectionally connected to the processor(s) 601, optionally by means of a memory control unit 607. The read-only memory 608 provides additional storage capacity. The memory 608 can be employed for saving the operating system 609, programs 610, data 611, applications 612, application programs, or similar. In many cases, but not invariably, the memory 608 is a secondary storage medium (such as a hard disk), which operates at a slower speed than the primary memory (e.g. the memory 603). The memory 608 can also be e.g. a magnetic, an optical or a transistorized, solid-body memory device (e.g. flash-based systems), or can comprise an arbitrary combination of the above-mentioned elements. In appropriate cases, the information memory 608 can also be integrated in the memory 603 in the form of a virtual memory.

The bus 640 connects a multiplicity of subsystems. The bus 640 can arbitrarily assume one of a number of types of bus structures, e.g. a memory bus, a memory controller, a peripheral bus, a local bus, and all combinations thereof, employing a multiplicity of bus architectures. Information and data can also be indicated by means of a display 632. Examples of a display 632 include, but not by way of limitation, a liquid crystal display (LCD), an organic liquid crystal display (OLED), a cathode ray tube (CRT), a plasma screen, or arbitrary combinations thereof. The display 632 can be connected to the processor(s) 601, memories 603, 608, input devices 633 and further components via the bus 640.

The output device 80 can be configured as an element of, or in the form of such a display 632.

The bus 640 can connect all the above-mentioned components to an external network, e.g. a cloud 630, at a network interface 620. The external network can be e.g. a LAN, WLAN, etc. This network can set up connections to further storage media, servers, printers or display devices. The network can provide access to telecommunication devices and the Internet. The bus 640 can connect all the above-mentioned components to a graphics controller 621 and a graphical user interface 622, which is connectable to at least one input device 633.

The bus 640 can connect all the above-mentioned components to an input interface 623, which is connectable to a least one input device 633. An input device can include e.g. a key panel, a keypad, a mouse, a stylus, a touchscreen, etc.

The input unit 9 can be configured as an element of, or in the form of an input device 633 of this type.

The bus 640 can connect all the above-mentioned components to an output interface 624, which is connectable to at least one output device 634. An output device 634 can comprise an illuminated indicator, a LED indicator, a display, e.g. a LCD, OLED, etc., or an interface to such a device.

The bus 640 can connect all the above-mentioned components to a memory access interface 625, which is connectable to at least one memory device 635. The bus 640 can connect all the above-mentioned components to a further memory access interface 626, which is connectable to at least one storage medium 636. A memory device 635 or storage medium 636 can comprise e.g. a solid-body device, a magnetic memory or an optical memory, in particular a non-volatile memory. During the operation of the control system, the storage medium can be isolated from the control system, with no resulting loss of data.

In each case, the display 632, input device 633, output device 634, memory device 635 or storage medium 636 can be arranged externally to the control system 600, or can be integrated therein. These devices can also be connected to the control system 600 via an Internet connection or other network interfaces.

The invention is not limited to the exemplary embodiments described. In the context of the invention, all the features described and/or illustrated are mutually combinable in an arbitrary manner.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A plasma state monitoring device for connecting to an impedance matching circuit for a plasma generation system, wherein the plasma state monitoring device is configured to:
a) capture a first group of time-varying measured values, wherein the time-varying measured values in the first group are dependent on an impedance which is detectable on one of terminals of the impedance matching circuit and are recorded in a temporally sequential manner;
b) capture a second group of time-varying measured values of at least one measured variable, wherein the at least one measured variable comprises at least one of:
i) a voltage;
ii) a current; or
iii) a phase relationship between the voltage and the current;
wherein the time-varying measured values of the at least one measured variable in the second group are recorded in a temporally sequential manner;
c) represent the first group of time-varying measured values in a first diagram, wherein the first diagram has no time axis, and represent the second group of time-varying measured values in a second diagram, wherein the second diagram comprises two axes, one of which is a time axis, wherein the first group of time-varying measured values and the second group of time-varying measured values have been captured within an at least partially identical time period, thereby enabling a state monitoring of the plasma generation system.

2. The plasma state monitoring device as claimed in claim 1, comprising:
an output device;
wherein the plasma state monitoring device is configured for simultaneous representation of the first diagram and the second diagram on the output device.

3. The plasma state monitoring device as claimed in claim 1, wherein the plasma state monitoring device is configured to capture the first group of time-varying measured values and the second group of time-varying measured values of the at least one measured variable at a measuring point within the plasma generation system.

4. The plasma state monitoring device as claimed in claim 3, wherein:
the measuring point is locatable in a region of an input terminal of the impedance matching circuit; or
the measuring point is locatable in a region of an output terminal of the impedance matching circuit.

5. The plasma state monitoring device as claimed in claim 1, comprising:
a measuring unit configured to measure the second group of time-varying measured values of multiple measured variables;
wherein the plasma state monitoring device is configured, from the measured time-varying measured values of the at least one measured variable of the second group, to calculate the time-varying measured values of the first group.

6. The plasma state monitoring device as claimed in claim 5, wherein:
the measuring unit is configured to measure the second group of time-varying measured values of a voltage and a current as the measured variables; and
the plasma state monitoring device is configured to calculate the phase relationship from the voltage and the current.

7. The plasma state monitoring device as claimed in claim 5, wherein:
the measuring unit comprises a directional coupler; or
the measuring unit comprises a current sensor and a voltage sensor.

8. The plasma state monitoring device as claimed in claim 5, wherein:
the measuring unit comprises a digitization device configured to digitize the second group of time-varying measured values, wherein the digitization device has a sampling rate in excess of 50 kHz.

9. The plasma state monitoring device as claimed in claim 8, comprising:
a memory device, wherein the digitization device is configured to save digitized time-varying measured values of the second group in the memory device.

10. The plasma state monitoring device as claimed in claim 1, wherein the plasma state monitoring device is configured to:
receive a trigger signal, and
in response to presence of the trigger signal, capture the first group of time-varying measured values and the second group of time-varying measured values of the at least one measured variable.

11. The plasma state monitoring device as claimed in claim 10, wherein the plasma state monitoring device is configured, upon each reception of the trigger signal, to capture a specific number of measured values in the first and the second group, and to represent the first group of time-varying measured values in the first diagram and the second group of time-varying measured values in the second diagram.

12. The plasma state monitoring device as claimed in claim 1, wherein:
a number of time-varying measured values in the first group corresponds to a number of time-varying measured values of the respective measured variable in the second group, or deviates therefrom by a maximum of 10%.

13. The plasma state monitoring device as claimed in claim 1, wherein the plasma state monitoring device is configured to plot at least a number or all of the time-varying measured values in the first group in the first diagram by colors, wherein the colors indicate time points at which the time-varying measured values in the first group have been captured.

14. The plasma state monitoring device as claimed in claim 13, wherein the colors are selected such that:
a) the time-varying measured values in the first group which have been captured previously are represented in a darker shade, and the time-varying measured values in the first group which have been captured subsequently are represented in a lighter shade; or
b) the time-varying measured values in the first group which have been captured previously are represented in a lighter shade, and the time-varying measured values in the first group which have been captured subsequently are represented in a darker shade.

15. The plasma state monitoring device as claimed in claim 1, wherein:
a first axis of the second diagram is a measured value axis, and a second axis of the second diagram is the time axis.

16. The plasma state monitoring device as claimed in claim 1, comprising:
an input unit configured to capture a user input.

17. The plasma state monitoring device as claimed in claim 16, wherein the plasma state monitoring device is configured to:
determine, via the input unit, which time-varying measured value in one of the first diagram and the second diagram is selected by a user; and
optically highlight a corresponding time-varying measured value in another one of the first diagram and the second diagram which has been captured within a same time period as the selected time-varying measured value.

18. The plasma state monitoring device as claimed in claim 17, wherein the plasma state monitoring device is configured to determine which of the time-varying measured values in the first group has been selected by a user in the first diagram via the input unit.

19. The plasma state monitoring device as claimed in claim 17, wherein the plasma state monitoring device is configured to optically highlight the selected time-varying measured value of the first group in the first diagram, by an enlarged representation and/or by a representation with a border.

20. The plasma state monitoring device as claimed in claim 17, wherein the plasma state monitoring device is configured to optically highlight the time-varying measured values of the respective measured variable in the second group which are represented in the second diagram and have been captured in the same time period as the selected time-varying measured value of the first group.

21. The plasma state monitoring device as claimed in claim 20, wherein the time-varying measured values of the respective measured variable in the second group are highlighted by:
a) enlarged representation and/or with a border; and/or
b) positioning a marking line over the time-varying measured values of the respective measured variable.

22. The plasma state monitoring device as claimed in claim 16, wherein the plasma state monitoring device is configured to determine which of the time-varying measured values of the respective measured variable in the second group is selected by a user in the second diagram via the input unit.

23. The plasma state monitoring device as claimed in claim 22, wherein the plasma state monitoring device is configured to:
a) determine a displacement of a marking line and/or of a cursor along the time axis in the second diagram, which is executed by the user via the input unit; and/or
b) determine a marking of a point and/or of a region in the second diagram which is executed by the user via the input unit;
thereby the plasma state monitoring device determines which of the time-varying measured values of the respective measured variable in the second group is selected.

24. The plasma state monitoring device as claimed in claim 22, wherein the plasma state monitoring device is configured to optically highlight the time-varying measured values in the first group which are represented in the first diagram and which have been captured in a same time period as the selected time-varying measured value of the at least one measured variable in the second group.

25. The plasma state monitoring device as claimed in claim 1, wherein the plasma state monitoring device is configured to:
plot a region in the first diagram; and
optically highlight the time-varying measured values of the first group in the first diagram which lie outside the region; and/or
optically highlight the time-varying measured values of the at least one measured variable of the second group in the second diagram which have been captured in a same time period as the time-varying measured values of the first group which lie outside the region.

26. The plasma state monitoring device as claimed in claim 25, wherein the plasma state monitoring device is configured to optically highlight the time-varying measured values of the at least one measured variable in the second group:
a) by an enlarged representation thereof and/or a representation thereof with a border;
b) by the representation thereof with a different color; or
c) by addition of a marking in direct proximity to the respective time-varying measured value of the respective measure variable in the second group.

27. The plasma state monitoring device as claimed in claim 25, wherein the plasma state monitoring device is configured to output an alarm, in an event that the time-varying measured values of the first group in the first diagram lie outside the region.

28. The plasma state monitoring device as claimed in claim 25, wherein the plasma state monitoring device is configured to define the region by reference to a user input which is executed via an input unit.

29. The plasma state monitoring device as claimed in claim 1, wherein the plasma state monitoring device is configured to progressively capture the time-varying measured values of the first group and the time-varying measured values of the second group, and to execute the representation thereof in the first diagram and the second diagram.

30. The plasma state monitoring device as claimed in claim 1, wherein the plasma state monitoring device is configured to capture time-varying measured values of a third group and time-varying measured values of a fourth group, and to represent the third group in a third diagram and to represent the fourth group in a fourth diagram.

31. A plasma generation system comprising:
the plasma state monitoring device as claimed in claim 1;
an impedance matching circuit;
a HF generator; and
at least one load;
wherein the HF generator is connected to an HF input of the impedance matching circuit;
wherein an HF output of the impedance matching circuit is connected to the at least one load;
wherein the first group of time-varying measured values is captured at the HF input of the impedance matching circuit; and
wherein the second group of time-varying measured values of the at least one measured variable is captured at the HF input of the impedance matching circuit.

32. A method for monitoring a plasma generation system by using a plasma state monitoring device for connecting to an impedance matching circuit, wherein the plasma state monitoring device is configured to execute the following process steps:
a) capturing a first group of time-varying measured values, wherein the time-varying measured values in the first group are dependent upon an impedance which is detectable on one of terminals of the impedance matching circuit, and are recorded in a temporally sequential manner;
b) capturing a second group of time-varying measured values of at least one measured variable, wherein the at least one measured variable comprises one of:
i) voltage;
ii) current; or
iii) the phase relationship between the voltage and the current;
wherein the time-varying measured values of the respective measured variable are captured in a temporally sequential manner;
c) representing the first group in a first diagram, wherein the first diagram is a diagram with no time axis, and representing the second group in a second diagram, wherein the second diagram comprises two axes, one of which is a time axis, wherein the time-varying measured values in the first group and the time-varying measured values of the respective measured variable in the second group have been captured within an at least partially identical time period, thereby enabling a state monitoring of the plasma generation system.
